(19) United States
(12) Patent Application Publication
(10) Pub. No.: US 2022/0037152 A1
(43) Pub. Date: Feb. 3, 2022

(54) Plasma Pre-Treatment Method To Improve Etch Selectivity And Defectivity Margin

(71) Applicant: Tokyo Electron Limited, Tokyo (JP)

(72) Inventors: Angelique Raley, Albany, NY (US); Qiaowei Lou, Albany, NY (US); Katie Lutker-Lee, Albany, NY (US)

(21) Appl. No.: 17/328,284

(22) Filed: May 24, 2021

Related U.S. Application Data
(60) Provisional application No. 63/058,800, filed on Jul. 30, 2020.

(51) Int. Cl. H01L 21/02; H01L 21/027; H01L 21/311

(52) U.S. Cl. CPC H01L 21/02315; H01L 21/31144; H01L 21/31116; H01L 21/0276

(57) ABSTRACT

Improved methods are provided for transferring a photoresist pattern onto one or more underlying layers. In the disclosed embodiments, etch selectivity between a photoresist layer and one or more underlying layers is improved by pre-treating the underlying layer(s) with a plasma before the photoresist layer is deposited and patterned to form a photoresist pattern. The plasma modifies the underlying layer(s) by implanting ions into the underlying layer(s) to form a modified layer. When the modified layer is subsequently etched to transfer the photoresist pattern onto the modified layer, the presence of ions within the modified layer increases the etch rate of the modified layer, compared to the etch rate that the underlying layer(s) would have exhibited without plasma pre-treatment. The increased etch rate of the modified layer improves etch selectivity between the photoresist layer and the modified layer and mitigates defects during the photoresist pattern transfer process.

This application claims priority to U.S. Provisional Patent Application No. 63/058,800, entitled, “Plasma Pre-Treatment Method to Improve Etch Selectivity and Defectivity Margin,” filed Jul. 30, 2020; the disclosure of which is expressly incorporated herein, in its entirety, by reference.

### BACKGROUND

The present disclosure relates to the processing of substrates, such as for example, semiconductor substrates. In particular, it provides a novel method to pattern substrates having very narrow pitch designs.

As geometries in substrate processing continue to shrink, the technical challenges to forming structures on substrates via photolithography techniques increase. As requirements for lower pitch structures arose, a variety of photolithography techniques have been utilized for achieving suitable photolithography for such narrow pitches including extreme ultraviolet (EUV) lithography (lithography utilizing wavelengths of light in the EUV range), multiple patterning schemes (such as self-aligned double patterning (SADP), self-aligned triple patterning (SATP), etc.), argon fluoride (ArF) lithography, or other narrow-pitch patterning techniques.

It has been found that as pitches and dimensions decrease, the line width roughness (LWR), line edge roughness (LER), contact edge roughness (CER), and local critical dimension uniformity (LCDU) performances degrade during the pattern transfer process. Further, the formation of photoresist scum in areas in which the photoresist should have been removed may create bridging between lines. Thus, as the feature size is reduced, LWR, LER, CER, LCDU, and photoresist scum have become recognized as critical concerns. The effects of LWR, LER, CER, LCDU, and photoresist scum are particularly problematic with EUV lithography, where the photoresist height is typically short and the pitch of the patterned photoresist is narrow.

FIGS. 1A-1D illustrate a process for transferring a photoresist pattern onto an underlying layer. As shown in FIG. 1A, the prior art process may generally begin by forming an underlying layer 104 on a substrate 100, which may also have additional layers 102. Note, as known in the art, the substrate 100 may comprise a variety of patterned layers which form the additional layers 102 as typically formed in the substrate processing art. In one example, the underlying layer 104 may include a hard mask layer. Other layers may be included above and/or below the hard mask layer, as is known in the art.

Next, a photoresist layer 106 may be formed on the underlying layer 104 (in FIG. 1B) and may be patterned (in FIG. 1C). In some cases, an EUV lithography process may be used to pattern the photoresist layer 106 to form an EUV photoresist pattern 108. After the lithography step, an etch process may be used to open or etch the underlying layer 104 to transfer the EUV photoresist pattern 108 onto the underlying layer 104 (in FIG. 1D). In FIG. 1D, the photoresist layer 106 has been stripped, and the EUV photoresist pattern 108 has been formed in the underlay layer 104. In some cases, a Reactive Ion Etch (RIE) process may be used to etch the underlying layer 104 using a dry etch chemistry. In some cases, the underlying layer 104 may include a hard mask layer, as noted above. In such cases, the hard mask layer may be utilized to subsequently operate as a mask layer for etching the pattern of the EUV photoresist pattern 108 into the additional layers 102. Alternatively, the final target layer into which the pattern is desired to be formed may be the underlying layer 104.

Unfortunately, the dry etch selectivity between the underlying layer 104 and the photoresist layer 106 may not be sufficient to mitigate defects, especially when patterning photoresist lines with relatively small height and narrow pitch. More specifically, this may occur when RIE or another etch process is used to open the underlying layer 104. For example, the height of the photoresist layer 106 and the relative etch rates between the photoresist layer 106 and the underlying layer 104 may lead to unacceptable EUV mask loss, uneven line height, line opens and bridges.

FIG. 1D illustrates an example of one possible result of EUV mask loss. As shown in FIG. 1D, some of the remaining structures in the etched underlying layer 104 have decreased in height. The structures with decreased height represent areas in which the etch broke through the photoresist layer 106 and started etching the underlying layer 104, when it was desirable to leave the underlying layer 104 intact. Thus, as shown in FIG. 1D, an uneven line height may occur in the prior art process shown in FIGS. 1A-1D. In some instances, portions of the underlying layer 104 may be completely etched. Regardless of whether the underlying layer 104 was decreased in height or completely removed, such effects may cause defects in the subsequent processing and operation of the device being formed on the substrate.

FIG. 2 illustrates a top view of a prior art portion of a patterned substrate 200. Because of the problems discussed above, the process margins utilized may result in degraded pattern lines. For example, the etching of the already thin resist may cause LWR/LER degradation of a prior art process. Further, attempts to minimize effects of etching the resist may also cause scumming, bridging and the like. As process margins decrease, resist thicknesses decrease and pitches decrease, and the net patterning effect may result in degraded lines having “wiggle” and rough edges in the patterned substrate 200, as illustrated in FIG. 2. For example, the patterned lines 202 illustrate large LWR, the patterned lines 204 illustrate large LER, and the patterned lines 206 illustrate line opens. In addition, scumming may result in bridges 208 being formed between the patterned lines. Though FIG. 2 illustrates LER and LWR effects, it will be recognized that degraded patterns may also include degraded CER for contacts and more generally degraded LCDU across the substrate.

As noted above, the defects produced in the patterned substrate 200 may be accentuated by poor etch selectivity between the underlying layer 104 and the photoresist layer 106, particularly with thin resists. Prior art processes may attempt to mitigate defects by tuning the etch recipe or adjusting the thickness of the photoresist pattern. However, the operation window is narrow between line opens and bridges. Thus, it would be desirable to provide a technique that improves etch selectivity between an underlying layer and a photoresist layer and reduces defectivity (such as LWR, LER, CER, LCDU, line opens and/or bridges) in the underlying layer during the photoresist pattern transfer process.

### SUMMARY

Methods and process flows are disclosed herein to perform photolithography pattern transfer. More specifically, embodiments of an improved method and process flow are provided herein for transferring a photoresist pattern onto one or more underlying layers. In the disclosed embodiments, the etch selectivity between a photoresist layer and one or more layers underlying the photoresist layer is improved by pre-treating the one or more underlying layers with a plasma before the photoresist layer is deposited and patterned to form a photoresist pattern. The plasma modifies the underlying layer(s) by implanting ions into the underlying layer(s),In some embodiments, the ion penetration depth, and thus, the thickness of the modified layer may be controlled by controlling the ion energy of the plasma. The modification of the underlying layer(s) enhances the etch rate of the underlying layer(s), and thus, provides improved relative etch rates between the photoresist layer and the underlying layer(s).

The presence of ions within the modified layer introduces defects within the modified layer and increases the etch rate of the modified layer compared to the etch rate that the underlying layer(s) would have exhibited without plasma pre-treatment. Increasing the etch rate of the modified layer improves etch selectivity when the photoresist pattern is subsequently transferred to the modified layer. By improving etch selectivity between the photoresist layer and the underlying layer(s), the techniques described herein may be used to mitigate defects that may otherwise occur during the photoresist pattern transfer process (such as, e.g., LWR, LER, CER, LCDU, line opens and/or bridges) if the underlying layer(s) were not pre-treated with the plasma. For example, the techniques described herein may be used to reduce LWR/LER of subsequently formed patterned lines, CER of patterned contacts and more generally LCDU of all patterns. In addition, the techniques described herein may be used to prevent line opens within patterned lines and/or bridges between the patterned lines.

In one exemplary embodiment, a first method for processing a substrate is provided. The method may comprise providing the substrate with at least one underlying layer and pre-treating the at least one underlying layer with a plasma to modify the at least one underlying layer, wherein ions from the plasma are implanted into the at least one underlying layer to form a modified layer. The method further comprises providing a photoresist layer overlying the modified layer and using a lithography technique to form a photoresist pattern in the photoresist layer. The method also comprises removing portions of the modified layer exposed by the photoresist pattern to transfer the photoresist pattern onto the modified layer, wherein the pre-treating the underlying layer with the plasma increases a rate at which the modified layer is removed compared to without pre-treatment.

In one embodiment of the first method, the plasma is generated from one or more processing gases selected from a group comprising hydrogen (H2), helium (He), argon (Ar), nitrogen (N2), borane (BH₃), and phosphine (PH₃). In another embodiment of the first method, the at least one underlying layer comprises a hard mask layer. In another embodiment of the first method, the at least one underlying layer comprises a silicon containing material. In yet another embodiment of the first method, the photoresist layer is an extreme ultraviolet (EUV) photoresist layer, and the lithography technique is an EUV lithography technique. In still another embodiment of the first method, the removing portions of the modified layer comprises performing an etch process to open the portions of the modified layer exposed by the photoresist pattern. In a more particular embodiment, the etch process is a plasma etch process. In another embodiment, the pre-treating the underlying layer with the plasma increases an etch rate of the modified layer compared to an etch rate of the underlying layer without pre-treatment. In a more particular embodiment, increasing the etch rate of the modified layer improves etch selectivity between the modified layer and the photoresist layer. In another embodiment, the pre-treating the underlying layer with the plasma improves line width roughness (LWR), line edge roughness (LER), contact edge roughness (CER) and/or local critical dimension uniformity (LCDU).

In another exemplary embodiment, a second method for processing a substrate is provided. The second method may comprise providing the substrate with at least one underlying layer and pre-treating the at least one underlying layer with a plasma to modify the at least one underlying layer, wherein the plasma is generated from one or more processing gases comprising hydrogen (H₂), nitrogen (N₂), borane (BH₃), phosphine (PH₃) and/or a noble gas, and wherein ions from the plasma are implanted into the at least one underlying layer to form a modified layer. The second method further comprises providing an extreme ultraviolet (EUV) photoresist layer overlying the modified layer and using an EUV lithography technique to form a photoresist pattern in the EUV photoresist layer. The second method also comprises etching portions of the modified layer exposed by the photoresist pattern with a dry etch process to transfer the EUV photoresist pattern onto the modified layer, wherein the pre-treating the at least one underlying layer with the plasma increases an etch rate of the modified layer and improves dry etch selectivity over the EUV photoresist layer.

In one embodiment of the second method, the at least one underlying layer comprises a silicon containing material. In another embodiment of the second method, the one or more processing gases comprise hydrogen (H₂). In still another embodiment, the second method further comprises controlling a bias voltage used to generate the plasma to control ion energy, which in turn, controls ion implantation depth, and thus, a thickness of the modified layer. In another embodiment of the second method, the dry etch process is a plasma etch process.

In another embodiment, a third method for processing a substrate is provided. The third method may comprise providing the substrate with at least one underlying layer, wherein the at least one underlying layer comprises a silicon containing material. The third method further comprises pre-treating the at least one underlying layer with a hydrogen (H₂) plasma to modify the at least one underlying layer, wherein H and H₂ ions from the hydrogen plasma are implanted into the at least one underlying layer to form a modified layer. The third method also comprises providing a photoresist layer overlying the modified layer and using a lithography technique to form a photoresist pattern in the photoresist layer. The third method further comprises etching portions of the modified layer exposed by the photoresist pattern to transfer the photoresist pattern onto the modified layer and form a modified layer pattern, wherein the pre-treating the at least one underlying layer with the hydrogen plasma improves etch selectivity during said etching and improves defectivity margin in the modified layer pattern.

In one embodiment of the third method, the photoresist layer is an extreme ultraviolet (EUV) photoresist layer. In another embodiment of the third method, the pre-treating the at least one underlying layer with the plasma improves etch selectivity by increasing an etch rate of the modified layer compared to an etch rate of the at least one underlying layer without pre-treatment. In another embodiment of the third method, the etch rate of the modified layer is 1.5 to 10 times greater than the etch rate of the underlying layer without pre-treatment. In another embodiment of the third method, the photoresist layer is an extreme ultraviolet (EUV) photoresist layer.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1D illustrate a prior art process for transferring a photoresist pattern onto an underlying layer.

FIG. 2 illustrates prior art examples of LWR, LER, line opens and line bridges that may occur in a patterned layer formed using the prior art process of FIGS. 1A-1D.

FIGS. 3A-3E illustrate one embodiment of an improved process for transferring a photoresist pattern onto an underlying layer.

FIG. 4 illustrates an example patterned layer that may be formed using the improved process of FIGS. 3A-3E.

FIGS. 5-7 illustrate exemplary methods for processing a substrate according to the techniques described herein.

### DETAILED DESCRIPTION

Methods and process flows are disclosed herein to perform photolithography pattern transfer. More specifically, embodiments of an improved method and process flow are provided herein for transferring a photoresist pattern onto one or more underlying layers. In the disclosed embodiments, the selectivity between a photoresist layer and one or more layers underlying the photoresist layer is improved by pre-treating the one or more underlying layers with a plasma before the photoresist layer is deposited and patterned to form a photoresist pattern. The plasma modifies the underlying layer(s) by implanting ions into the underlying layer(s). In some embodiments, the ion penetration depth, and thus, the thickness of the modified layer may be controlled by controlling the ion energy of the plasma.

The presence of ions within the modified layer introduces defects within the modified layer and increases the etch rate of the modified layer compared to the etch rate that the underlying layer(s) would have exhibited without plasma pre-treatment. Increasing the etch rate of the modified layer improves etch selectivity when the photoresist pattern is subsequently transferred to the modified layer. By improving etch selectivity between the photoresist layer and the underlying layer(s), the techniques described herein may be used to mitigate defects that may otherwise occur during the photoresist pattern transfer process if the underlying layer(s) were not pre-treated with the plasma. For example, the techniques described herein may be used to reduce LWR/LER of subsequently formed patterned lines, reduce CER of subsequently patterned contacts and more generally improve LCDU of all patterns. In addition, the techniques described herein may be used to prevent line opens within patterned lines and/or bridges between patterned lines.

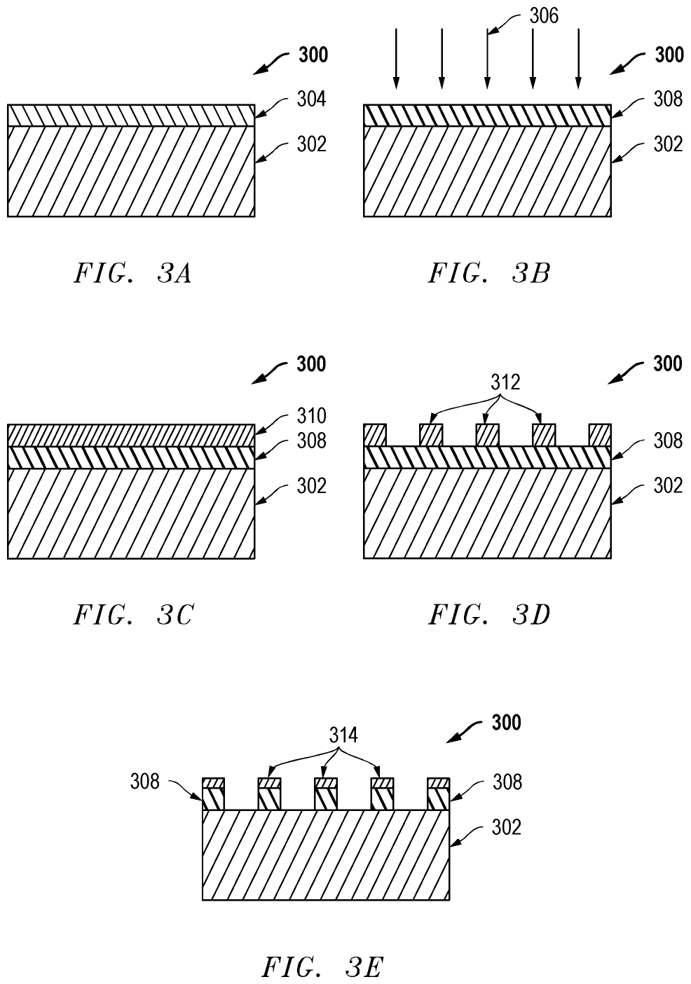

An exemplary embodiment of an improved process for transferring a photoresist pattern onto an underlying layer is depicted in FIGS. 3A-3E. As shown in FIG. 3A, the process may generally begin by providing a substrate 300 and forming one or more underlying layer(s) 304 and additional layers 302. In one embodiment, the one or more underlying layer(s) 304 may comprise a hard mask layer, such as but not limited to, a silicon nitride (SiN) layer. However, the underlying layer(s) 304 are not strictly limited to a hard mask layer and may include one or more layers formed above and/or below the hard mask layer. For example, the one or more underlying layer(s) 304 may additionally include one or more antireflective (ARC) layers. Other layers may additionally or alternatively be included within the one or more underlying layer(s) 304. Further, the underlying layer(s) 304 need not be utilized as a hard mask layer, and instead, may be a final intended target layer within which a pattern is intended to be formed.

The one or more underlying layer(s) 304 may be formed using any known materials and any known methods. As noted above, silicon nitride (SiN) is one example of a material that may be included within the one or more underlying layer(s) 304. Other materials may also be used. For example, the one or more underlying layer(s) 304 may comprise silicon, silicon oxide, silicon nitride or other silicon containing materials. It is additionally noted that the one or more underlying layer(s) 304 are not strictly limited to silicon-containing materials and could alternatively include metal oxides. The underlying layer(s) 304 can be formed using one or more deposition processes including an atomic layer deposition (ALD) process, a chemical vapor deposition (CVD) process, a physical vapor deposition (PVD) process, a plasma deposition process, etc. Other deposition processes, or combinations of processes, can also be used to form the one or more underlying layer(s) 304.

After the one or more underlying layer(s) 304 are formed on the substrate 300, the underlying layer(s) 304 may be pre-treated with a plasma 306 to form a modified layer 308. As known in the art, plasma may be generated by supplying one or more process gases to a processing chamber while power is applied to one or more electrodes disposed above and/or below a substrate disposed within the processing chamber. In one example embodiment, a source voltage can be applied to an upper electrode arranged above a substrate, and a bias voltage can be applied to a lower electrode arranged below the substrate to generate a high-frequency electric field between the upper and lower electrodes. The high-frequency electric field dissociates and converts the one or more process gases supplied to the processing chamber into a plasma, which can be used in various types of treatments such as, but not limited to, plasma etching, deposition and/or sputtering.

As known in the art, a plasma may be an ionized gas phase substance that consists of (positive and/or negative) ions, electrons, and neutral atoms/molecules that grossly maintain charge neutrality. In the embodiments disclosed herein, the plasma 306 generated during the pre-treatment step modifies the one or more underlying layer(s) 304 by implanting ions into the underlying layers. The ion implantation depth, and thus, the thickness of the modified layer 308 generally depends on the material used to form the underlying layer(s) 304, the process gas(es) used to generate the plasma 306 and the associated ions, the ion energy and the processing time. In some embodiments, the bias voltage may be selected or adjusted to control the ion energy, and thus, the depth to which the ions are implanted within the underlying layer(s) 304 to from the modified layer 308.

Various plasma chemistries may be used in the pre-treatment step to modify the underlying layer(s) 304 and form the modified layer 308. In one embodiment, a hydrogen (H₂) plasma may be used to pre-treat (i.e., modify) an underlayer comprising silicon nitride. In one exemplary embodiment, the hydrogen (H₂) plasma may be performed with process conditions of 0 W to 500 W source power, 20 W to 200 W bias power, 5 mT to 50 mT pressure, '110° C. to 100° C. (and more preferably 40° C.) electrostatic chuck temperature, and 100 standard cubic centimeters (SCCM) H₂ gas flow. Other gases, such as for example, argon (Ar), nitrogen (N₂), helium (He), borane (BH₃), phosphine (PH₃), etc. may also be added to the gas flow. The ion implantation modification step may also be achieved by using ion beam implantation or gas cluster ion beam implantation.

Although one example embodiment is described herein with regard to a hydrogen (H₂) plasma, other plasmas may also be utilized to pre-treat the one or more underlying layer(s) 304. Plasmas containing nitrogen (N₂), borane (BH₃), or phosphine (PH₃) may also be utilized. Exemplary plasmas that may also be utilized further include plasmas containing noble gases, such as but not limited to, helium (He) and argon (Ar). Combinations of such gases may also be utilized. Further, other gases may be utilized in combination with the gases listed above. For example, other gases may be added to the plasma, as the plasma is not limited to only those gases listed herein which are merely exemplary. For example, other inert gases or other gases that are not inert gases may be added to the process.

After the underlying layer(s) 304 are pre-treated with plasma 306, a photoresist layer 310 may be formed on the modified layer 308 (in FIG. 3C) and may be patterned (in FIG. 3D). In some embodiments, a photolithography process may be used to pattern the photoresist layer 310 to form photoresist 312 patterned lines. In one embodiment, an EUV lithography process may be used to pattern the photoresist layer 310 and form EUV photoresist patterned lines. In one exemplary embodiment, the EUV photoresist may be a standard organic chemically-amplified resist (CAR) EUV photoresist. Other EUV photoresists may also be used.

Although the embodiments described herein are presented in the context of use with EUV photolithography and EUV photoresists, it will be recognized that the concepts described herein may be utilized with a wide range of lithography techniques and photoresists. For example, the concepts described herein may be utilized with other photoresists including ultraviolet photoresists, ArF photoresists and others. Thus, it will be recognized that although the concepts described herein are provided with regard to EUV lithography techniques, the concepts described herein may be also applicable to other lithography techniques, including those with pitches narrower than those achievable with EUV lithography techniques.

It is further noted that although the examples shown herein are illustrated with respect to photoresist line patterns (or patterned lines), it will be recognized that the concepts described herein may be utilized with other photoresist patterns, such as hole patterns, block patterns, etc. Thus, it will be recognized that the particular patterns in the photoresist layers shown herein are merely exemplary.

After the lithography step, portions of the modified layer 308 exposed and not protected by the photoresist 312 may be removed to transfer the photoresist 312 pattern onto the modified layer 308 (in FIG. 3E). In some embodiments, the photoresist 312 pattern may be transferred onto the modified layer 308 to form a modified layer pattern 314, which may be used in one or more subsequent processing steps. In some embodiments, the modified layer pattern 314 may be a hard mask pattern that is used to replicate the photoresist 312 pattern into the additional layers 302.

In some embodiments, an etch process may be used to open (or etch) the portions of the modified layer 308 exposed by the photoresist 312 pattern to transfer the photoresist pattern to the modified layer 308 and form the modified layer pattern 314. In one embodiment, a dry etch process may be used to etch the exposed portions of the modified layer 308. For example, a plasma etch process may be used. In one example embodiment, a Reactive Ion Etch (RIE) process may be used to etch the exposed portions of the modified layer 308 using any suitable dry etch chemistry. Example dry etch chemistries may include, but are not limited to, fluorocarbon chemistries. Exemplary fluorocarbon chemistries include, but are not limited to CF₄, CHF₃, and CH₃F. It is noted that the etch process used herein is not strictly limited to RIE. Other dry etch processes may also be used. In still other embodiments, a wet etch process may be used to remove the exposed portions of the modified layer 308.

The techniques described herein improve etch selectivity during the photoresist transfer process shown in FIG. 3E by pre-treating the one or more underlying layer(s) 304 with a plasma 306 before depositing and patterning the photoresist layer 310. The plasma 306 pre-treatment step shown in FIG. 3B modifies the underlying layer(s) 304 by implanting ions into the underlying layer(s). In one example, hydrogen ions (H/H₂) may be implanted into the underlying layer(s) 304 to form the modified layer 308 shown in FIG. 3B. As noted above, the ion implantation depth, and thus, the thickness of the modified layer 308 generally depends on the material used to form the underlying layer(s) 304, the process gas(es) used to generate the plasma 306, the ion energy and the processing time.

The presence of ions within the modified layer 308 introduces defects into the modified layer 308 and increases the etch rate of the modified layer 308 compared to the etch rate that the underlying layer(s) 304 would have exhibited without plasma pre-treatment. In one example embodiment, the etch rate of the modified layer 308 may be 1.5 to 10 times greater than the etch rate of the underlying layer(s) 304 without pre-treatment. Increasing the etch rate of the modified layer 308 improves etch selectivity when the photoresist 312 pattern is subsequently transferred to the modified layer in FIG. 3E. In one example embodiment, the selectivity exhibited during the pattern transfer process may be 5:1 with the plasma pre-treatment described herein, compared to 2:1 without pre-treatment.

By improving etch selectivity between the photoresist 312 and the underlying layer(s) 304, the techniques described herein improve the defectivity margin in the subsequently formed modified layer pattern 314. By providing better selectivity, the disclosed techniques may reduce or eliminate defects (such as, for example, LWR, LER, CER, LCDU, line opens and/or bridges) that may otherwise occur during the photoresist pattern transfer process if the underlying layer(s) 304 were not pre-treated with the plasma 306.

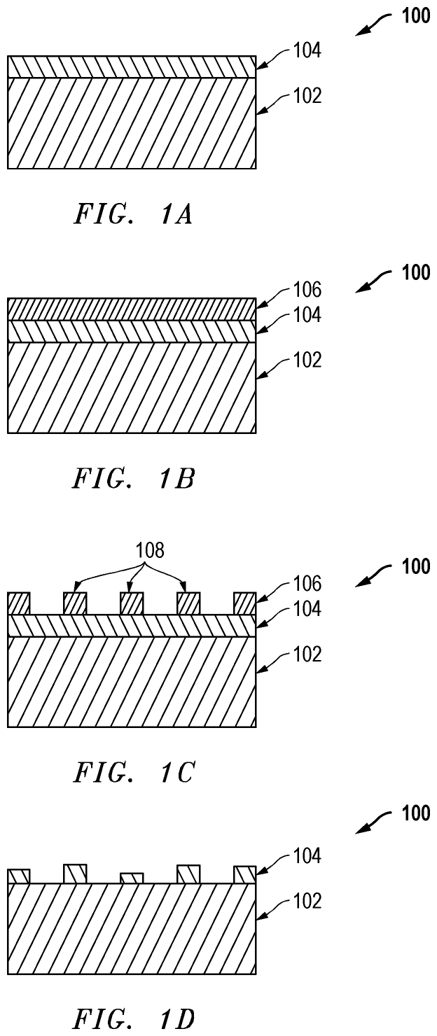

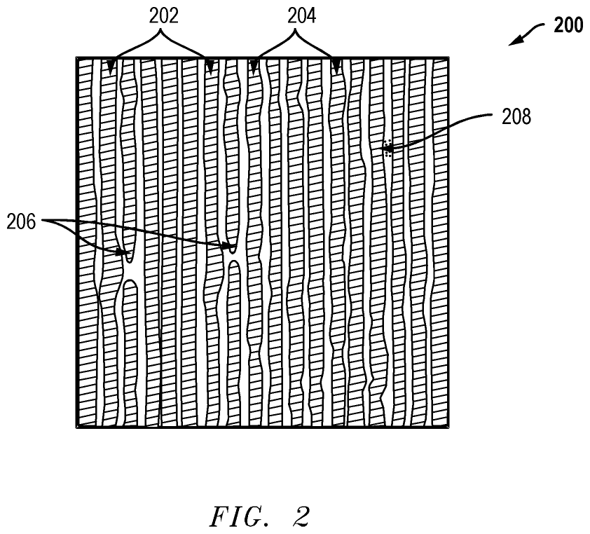

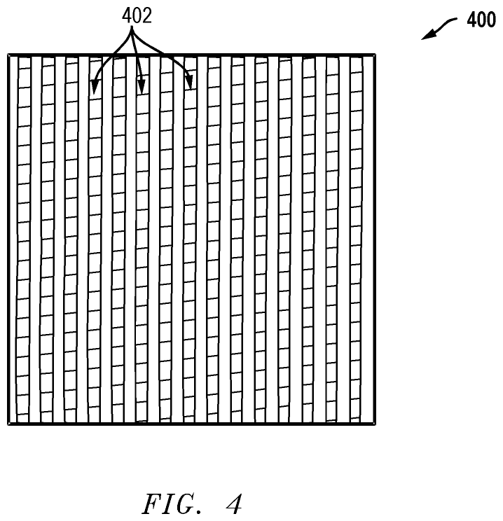

Exemplary results of the pre-treatment techniques described herein are shown in FIGS. 3E and 4. As shown in FIG. 3E, the pre-treatment techniques described herein prevent mask loss and uneven line height (see, e.g., FIG. 1D) during the photoresist pattern transfer process. FIG. 4 illustrates a top view of a portion of a patterned substrate 400 having a plurality of patterned lines 402 formed in accordance with the techniques described herein. As shown in the comparison of FIGS. 2 and 4, the patterned lines 402 formed using the pre-treatment techniques described herein exhibit much less LWR and LER than the patterned lines 202 and 204 formed without pre-treatment. In some embodiments, the pre-treatment techniques described herein may be used to reduce LWR/LER by 15% or more. In one example embodiment, the disclosed pre-treatment techniques may reduce LWR/LER by more than 5%, and more preferably, more than 15%. The pre-treatment techniques described herein may also be used to avoid line opens and/or bridges (see, FIG. 2) that may occur when a prior art process is used to form the patterned lines. Similarly percentage improvements may also be obtained for CER and LCDU.

The pre-treatment techniques described herein may be used with a wide range of photolithography techniques, structures and process flows. Thus, it will be recognized that the structures shown in FIGS. 3A-3E are merely exemplary and other layers and combinations of layers may be utilized. For example, one, more than one, or no other lithography layers may be provided between the photoresist layer 310 and the modified layer 308. Therefore, it will be recognized that the particular layers and thicknesses shown and described with relation to in FIGS. 3A-3E are merely exemplary and other layers and/or thicknesses may be utilized. In addition, the modified layer 308 may overlie other layers of substrate 300, or other layers formed on top of substrate 300.

The substrate 300 may be any substrate for which the use of patterned features is desirable. In one embodiment, the substrate may be a substrate that has been subject to multiple semiconductor processing steps which yield a wide variety of structures and layers, all of which are known in the substrate processing art, and which may be considered to be part of the substrate. For example, in one embodiment, the substrate may be a semiconductor wafer having one or more semiconductor processing layers formed thereon. In one embodiment, the concepts disclosed herein may be utilized at a back end of line (BEOL) processing step. In another embodiment, the concepts disclosed herein may be utilized at a front end of line (FEOL) processing step.

As mentioned, it will be recognized that a particular stack of lithography layers may vary while still obtaining the benefits of the concepts described herein. Thus, for example, more or less lithography layers may be utilized. For example, an antireflective layer need not be utilized or multiple antireflective layers may be utilized (such as, for example, the use of both an antireflective coating (ARC) layer and a bottom antireflective coating (BARC) layer). Further, the particular composition of each layer may vary and the layers may be deposited in a variety of manners, as would be recognized in the art. Likewise the use of a hard mask layer is optional. Further, the techniques described herein may be utilized with any of a wide variety of materials used for the various lithography layers and underlying layers that are known in the substrate processing art, as the techniques described herein are not limited to particular materials.

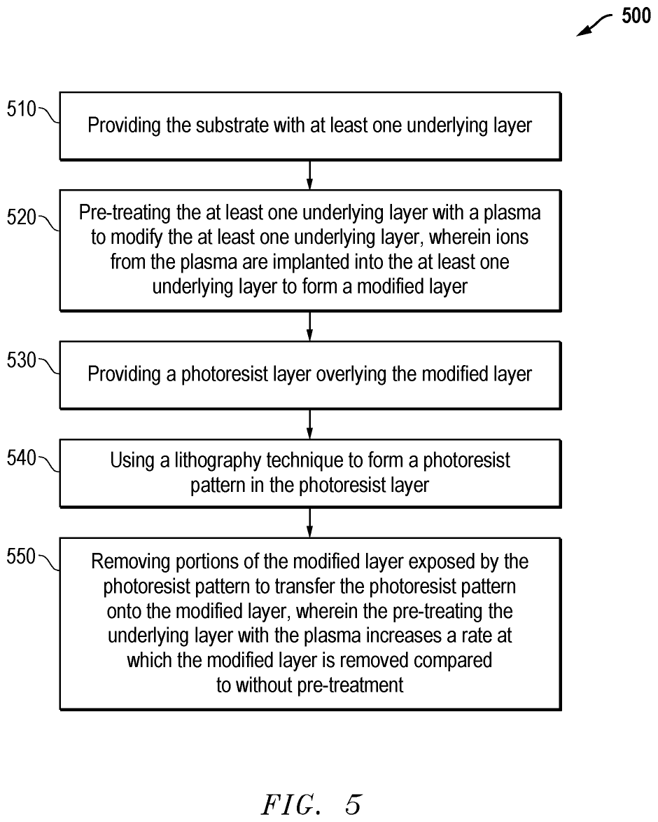

FIGS. 5-7 illustrate exemplary methods for use of the processing techniques described herein. It will be recognized that the embodiments of FIGS. 5-7 are merely exemplary, and additional methods may utilize the techniques described herein. Further, additional processing steps may be added to the methods shown in the FIGS. 5-7, as the steps described are not intended to be exclusive. Moreover, the order of the steps is not limited to the order shown in the figures as different orders may occur and/or various steps may be performed in combination or at the same time.

FIG. 5 illustrates a method 500 for processing a substrate. The method 500 comprises providing the substrate with at least one underlying layer (in step 510) and pre-treating the at least one underlying layer with a plasma to modify the at least one underlying layer (in step 520). During the pre-treatment step, ions from the plasma are implanted into the at least one underlying layer to form a modified layer. Next, the method 500 comprises providing a photoresist layer overlying the modified layer (in step 530), using a lithography technique to form a photoresist pattern in the photoresist layer (in step 540) and removing portions of the modified layer exposed by the photoresist pattern to transfer the photoresist pattern onto the modified layer (in step 550). In method 500, pre-treating the underlying layer with the plasma (in step 520) increases a rate at which the modified layer is removed (in step 550) compared to without pre-treatment.

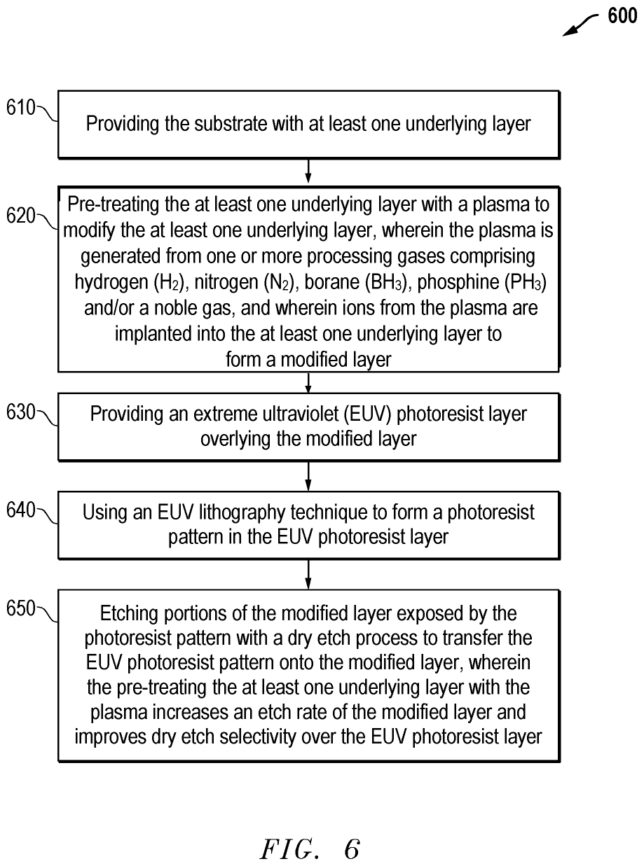

FIG. 6 illustrates a method 600 for processing a substrate. The method 600 comprises providing the substrate with at least one underlying layer (in step 610) and pre-treating the at least one underlying layer with a plasma to modify the at least one underlying layer (in step 620). In method 600, the plasma is generated from one or more processing gases comprising hydrogen (H₂), nitrogen (N2), borane (BH3), phosphine (PH3) and/or a noble gas(es). During the pre-treatment step, ions from the plasma are implanted into the at least one underlying layer to form a modified layer. Next, the method 600 comprises providing an extreme ultraviolet (EUV) photoresist layer overlying the modified layer (in step 630), using an EUV lithography technique to form a photoresist pattern in the EUV photoresist layer (in step 640), and etching portions of the modified layer exposed by the photoresist pattern with a dry etch process to transfer the EUV photoresist pattern onto the modified layer (in step 650). In method 600, pre-treating the at least one underlying layer with the plasma (in step 620) increases an etch rate of the modified layer (in step 650) and improves dry etch selectivity over the EUV photoresist layer.

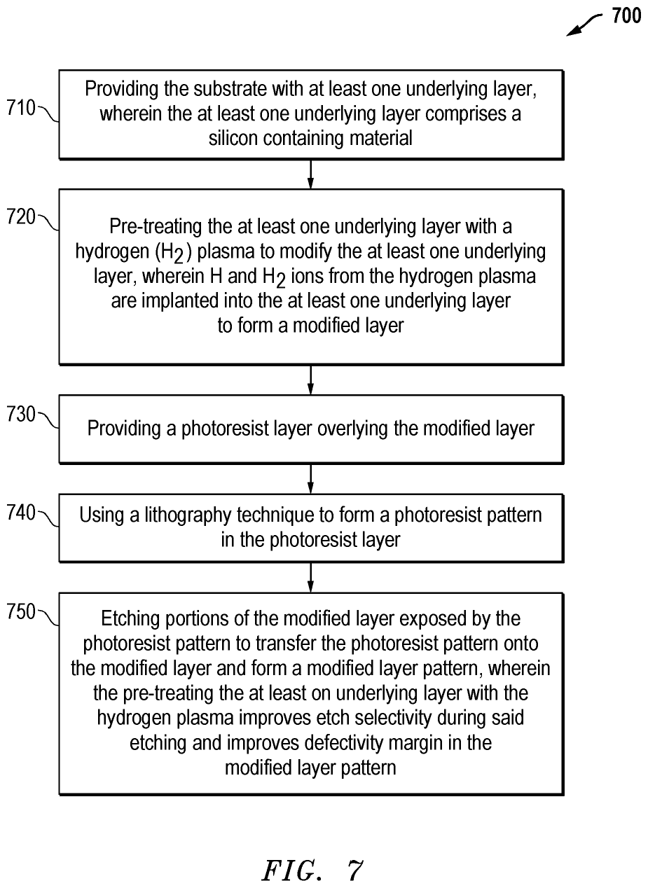

FIG. 7 illustrates a method 700 for processing a substrate. The method 700 may comprise providing the substrate with at least one underlying layer, wherein the at least one underlying layer comprises a silicon-containing material (in step 710), and pre-treating the at least one underlying layer with a hydrogen (H2) plasma to modify the at least one underlying layer (in step 720). During the pre-treatment step, H and H2 ions from the hydrogen plasma are implanted into the at least one underlying layer to form a modified layer. Next, the method 700 comprises providing a photoresist layer overlying the modified layer (in step 730), using a lithography technique to form a photoresist pattern in the photoresist layer (in step 740), and etching portions of the modified layer exposed by the photoresist pattern to transfer the photoresist pattern onto the modified layer and form a modified layer pattern (in step 750). In method 700, pre-treating the at least one underlying layer with the hydrogen plasma (in step 720) improves etch selectivity during said etching (in step 750) and improves defectivity margin in the modified layer pattern.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Systems and methods for processing a substrate are described in various embodiments. The substrate may include any material portion or structure of a device, particularly a semiconductor or other electronics device, and may, for example, be a base substrate structure, such as a semiconductor substrate or a layer on or overlying a base substrate structure such as a thin film. Thus, substrate is not intended to be limited to any particular base structure, underlying layer or overlying layer, patterned or unpatterned, but rather, is contemplated to include any such layer or base structure, and any combination of layers and/or base structures.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described systems and methods will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for processing a substrate, comprising:
providing the substrate with at least one underlying layer;
pre-treating the at least one underlying layer with a plasma to modify the at least one underlying layer, wherein ions from the plasma are implanted into the at least one underlying layer to form a modified layer;
providing a photoresist layer overlying the modified layer;
using a lithography technique to form a photoresist pattern in the photoresist layer; and
removing portions of the modified layer exposed by the photoresist pattern to transfer the photoresist pattern onto the modified layer,
wherein the pre-treating the underlying layer with the plasma increases a rate at which the modified layer is removed compared to without pre-treatment.

2. The method of claim 1, wherein the plasma is generated from one or more processing gases selected from a group comprising hydrogen (H₂), helium (He), argon (Ar), nitrogen (N₂), borane (BH₃), and phosphine (PH₃).

3. The method of claim 2, wherein the one or more processing gases comprise hydrogen (H₂).

4. The method of claim 1, wherein the at least one underlying layer comprises a hard mask layer.

5. The method of claim 1, wherein the at least one underlying layer comprises a silicon-containing material.

6. The method of claim 1, wherein the photoresist layer is an extreme ultraviolet (EUV) photoresist layer, and wherein the lithography technique is an EUV lithography technique.

7. The method of claim 1, wherein the removing portions of the modified layer comprises performing an etch process to open the portions of the modified layer exposed by the photoresist pattern.

8. The method of claim 7, wherein the pre-treating the underlying layer with the plasma increases an etch rate of the modified layer compared to an etch rate of the underlying layer without pre-treatment.

9. The method of claim 8, wherein increasing the etch rate of the modified layer improves etch selectivity between the modified layer and the photoresist layer.

10. The method of claim 1, wherein the pre-treating the underlying layer with the plasma improves line width roughness (LWR), line edge roughness (LER), contact edge roughness (CER) and/or local critical dimension uniformity (LCDU).

11. A method for processing a substrate, comprising:
providing the substrate with at least one underlying layer;
pre-treating the at least one underlying layer with a plasma to modify the at least one underlying layer, wherein the plasma is generated from one or more processing gases comprising hydrogen (H₂), nitrogen (N₂), borane (BH₃), phosphine (PH3) and/or a noble gas, and wherein ions from the plasma are implanted into the at least one underlying layer to form a modified layer;
providing an extreme ultraviolet (EUV) photoresist layer overlying the modified layer;
using an EUV lithography technique to form an EUV photoresist pattern in the EUV photoresist layer; and
etching portions of the modified layer exposed by the EUV photoresist pattern with a dry etch process to transfer the EUV photoresist pattern onto the modified layer,
wherein the pre-treating the at least one underlying layer with the plasma increases an etch rate of the modified layer and improves dry etch selectivity over the EUV photoresist layer.

12. The method of claim 11, wherein the at least one underlying layer comprises a silicon containing material.

13. The method of claim 11, wherein the one or more processing gases comprise hydrogen (H₂).

14. The method of claim 11, further comprising controlling a bias voltage used to generate the plasma to control ion energy, which in turn, controls ion implantation depth, and thus, a thickness of the modified layer.

15. The method of claim 11, wherein the dry etch process is a plasma etch process.

16. A method for processing a substrate, comprising:
providing the substrate with at least one underlying layer, wherein the at least one underlying layer comprises a silicon-containing material;
pre-treating the at least one underlying layer with a hydrogen (H₂) plasma to modify the at least one underlying layer, wherein H and H₂ ions from the hydrogen plasma are implanted into the at least one underlying layer to form a modified layer;
providing a photoresist layer overlying the modified layer;
using a lithography technique to form a photoresist pattern in the photoresist layer; and
etching portions of the modified layer exposed by the photoresist pattern to transfer the photoresist pattern onto the modified layer and form a modified layer pattern,
wherein the pre-treating the at least one underlying layer with the hydrogen plasma improves an etch selectivity during said etching and improves defectivity margin in the modified layer pattern.

17. The method of claim 16, wherein the photoresist layer is an extreme ultraviolet (EUV) photoresist layer.

18. The method of claim 16, wherein the pre-treating the at least one underlying layer with the hydrogen plasma improves the etch selectivity by increasing an etch rate of the modified layer compared to an etch rate of the at least one underlying layer without pre-treatment.

19. The method of claim 18, wherein the etch rate of the modified layer is 1.5 to 10 times greater than the etch rate of the underlying layer without pre-treatment.

20. The method of claim 18, wherein the photoresist layer is an extreme ultraviolet (EUV) photoresist layer.
